(19) United States
(12) Patent Application Publication
(10) Pub. No.: US 2012/0162873 A1
(43) Pub. Date: Jun. 28, 2012

(54) PUSH BUTTON ASSEMBLY AND ELECTRONIC DEVICE HAVING SAME

(75) Inventors: ZHONG-JIE LUO, Shenzhen City (CN); WEI ZENG, Shenzhen City (CN); JIE LI, Shenzhen City (CN); QIANG WANG, Shenzhen City (CN); TE-SHENG JAN, Tu-Cheng (TW); CHUN-CHE YEN, Tu-Cheng (TW); YU-TAO CHEN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD ., Shenzhen City (CN)

(21) Appl. No.: 13/241,139

(22) Filed: Sep. 22, 2011

(30) Foreign Application Priority Data
Dec. 28, 2010 (CN) 201010609106.3

(51) Int. Cl. H05K 5/02; H05K 7/00

(52) U.S. Cl. 361/679.01; 292/2

(57) ABSTRACT

A push button assembly includes a push button and a sheet. The push button includes a panel body and a sidewall protruding from the panel body. The panel body includes a protrusion. The sidewall includes at least one rib protruding from an inner surface thereof. The sheet defines a through hole and includes a tab in the through hole. The tab includes a distal edge shaped conforming to an outer surface of the protrusion. The protrusion passes through the through hole and contacts the distal edge of the tab, and the at least one rib abuts against an edge of the sheet in a manner so as to cause deformation the tab. The disclosure also provides an electronic device having such push button assembly.

### BACKGROUND

1. Technical Field

The present disclosure relates to a push button assembly and an electronic device having such push button assembly.

2. Description of Related Art

Push buttons include protruding tabs for being inserted into holes of covers to assemble the push buttons to the covers. Usually there is a gap between the push button and the hole, which has a negative influence on the assembly.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partial, isometric view of an internal structure of an electronic device according to an exemplary embodiment.

FIG. 2 is an exploded view of the electronic device of FIG. 1.

FIG. 3 is a partial, schematic view of the push button assembly of the electronic device in FIG. 1.

### DETAILED DESCRIPTION

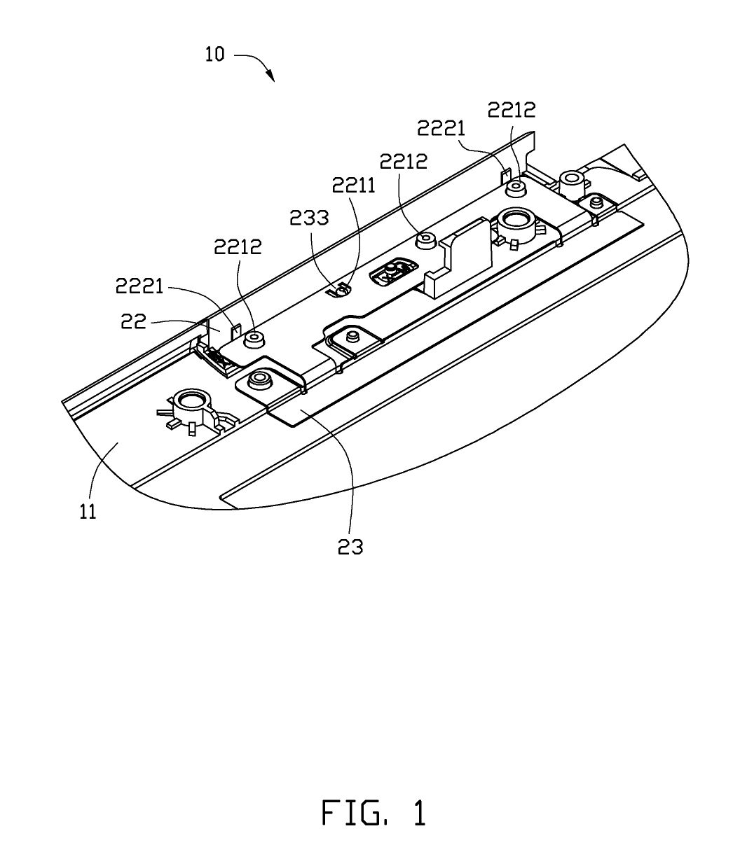

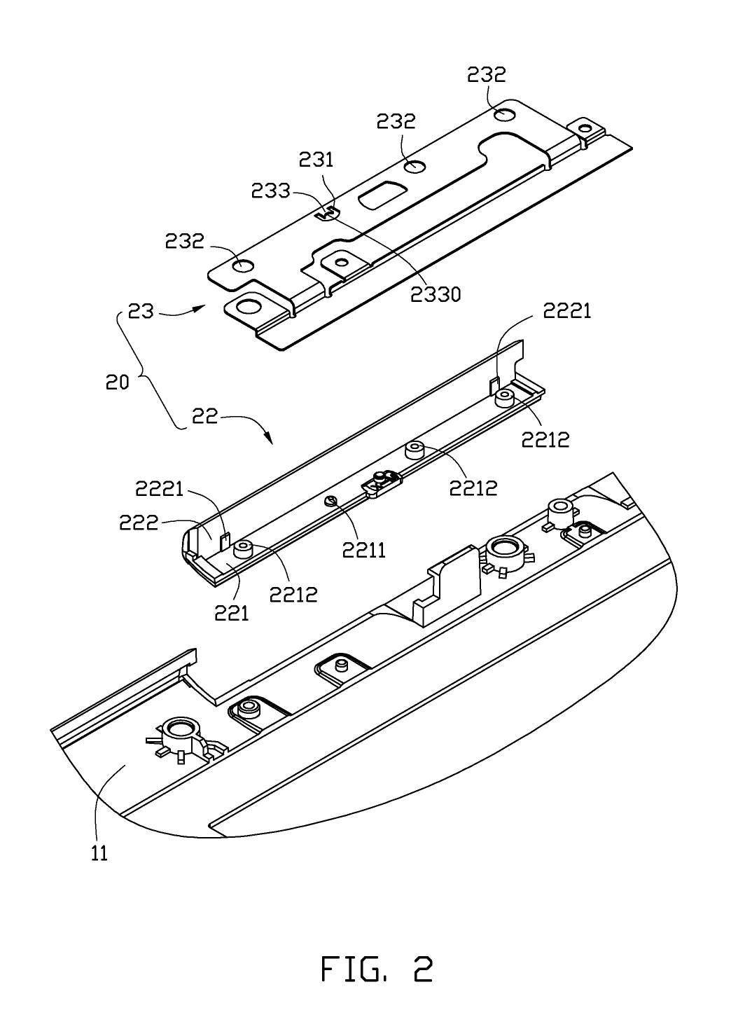

Referring to FIGS. 1, and 2, an electronic device 10 includes a cover 11 and a push button assembly 20. The push button assembly 20 includes a push button 22 and a metal sheet 23. The metal sheet 23 is fixed to the cover 11. The push button 22 is firmly connected to the cover 11 via the metal sheet 23.

The push button 22 includes a panel body 221 and an elongated sidewall 222 protruding from the panel body 221. The panel body 221 is substantially a planar plate. The panel body 221 includes a protrusion 2211 and three posts 2212 protruding from the panel body 221. The metal sheet 23 defines a through hole 231 for receiving the protrusion 2211, and three receiving holes 232 for receiving the posts 2212. The metal sheet 23 further includes a tab 233 in the through hole 231. The tab 233 includes a distal edge 2330 shaped conforming to an outer surface of the protrusion 2211 at the distal end of the tab 233.

The sidewall 222 extends along the lengthwise direction of the panel body 221 from one end to the opposite end. The sidewall 222 includes a number of ribs 2221 protruding from one side thereof. In the exemplary embodiment, the number of the ribs 2221 is two and the two ribs 2221 are respectively located at opposite ends of the sidewall 222. In an alternative embodiment, the ribs 2221 is strip-shaped and located at the middle of the sidewall 222.

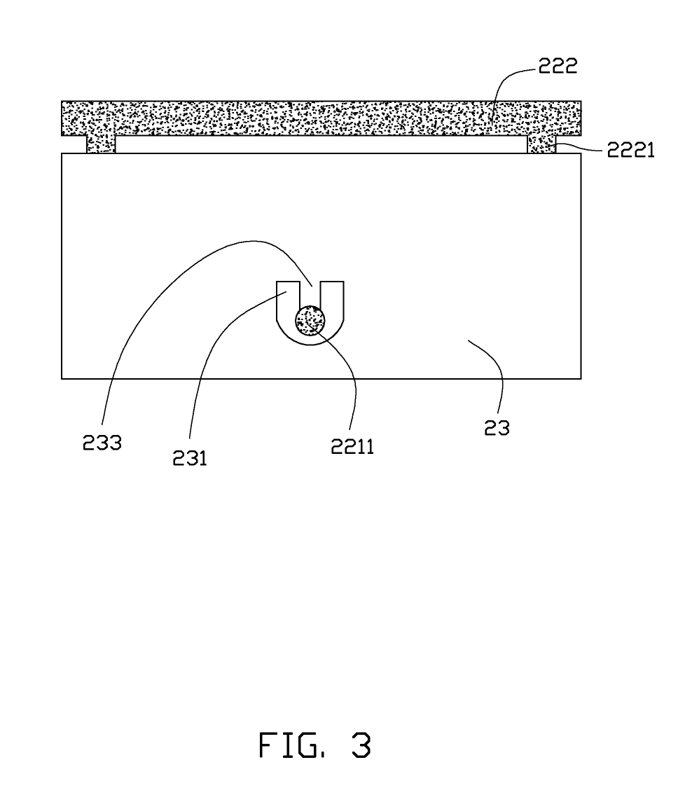

Referring to FIGS. 1 and 3, in assembly, the push button 22 and the metal sheet 23 are oriented so the protrusion 2211 is aligned with the through hole 231. The metal sheet 23 is then pushed toward the push button 22 to allow the protrusion 2211 to pass through the through hole 231 and contact the cambered surface 2330. When the ribs 2221 abut against the edge of the metal sheet 23, the tab 233 is slightly deformed because of the pressure from the protrusion 2211, which in return causes the edge of the metal sheet 23 to firmly abut against the ribs 2221. Therefore, the push button 22 cannot move along the radial direction of through hole 231. The posts 2212 pass through the receiving holes 232 and the distal ends thereof are riveted to fix the push button 22 to the metal sheet 23. When the metal sheet 23 is fixed to the cover 11, the push button 22 is also fixed to the cover 11 and is immovable relative to the cover 11.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A push button assembly comprising:
a push button comprising a panel body and a sidewall protruding from the panel body, the panel body comprising a protrusion, the sidewall comprising at least one rib protruding from an inner surface thereof; and
a sheet defining a through hole, the sheet comprising a tab in the through hole, the tab comprising a distal edge shaped conforming to an outer surface of the protrusion;
wherein the protrusion passes through the through hole and contacts the distal edge of the tab, and the at least one rib abuts against an edge of the sheet in a manner so as to cause deformation of the tab.

2. The push button assembly claim 1, wherein the at least one rib includes two ribs, and the two ribs are respectively located at opposite ends of the sidewall.

3. The push button assembly of claim 1, wherein the at least one rib is strip-shaped and located at the middle of the sidewall.

4. The push button assembly of claim 1, wherein the panel body further comprises a plurality of posts, the sheet further defines a plurality of receiving holes, the plurality of posts extend through the plurality of receiving holes and top ends of the plurality of posts are riveted to fix the push button to the sheet.

5. An electronic device comprising:
a push button assembly comprising:
a push button comprising a panel body and a sidewall protruding from the panel body, the panel body comprising a protrusion, the sidewall comprising at least one rib protruding from an inner surface thereof; and
a sheet defining a through hole, the sheet comprising a tab in the through hole, the tab comprising a distal edge shaped conforming to an outer surface of the protrusion;
wherein the protrusion passes through the through hole and contacts the distal edge of the tab, and the at least one rib abuts against an edge of the sheet in a manner such that the tab is deformed.

6. The electronic device claim 5, wherein the at least one rib includes two ribs, and the two ribs are respectively located at opposite ends of the sidewall.

7. The electronic device of claim 5, wherein the at least one rib is strip-shaped and located at the middle of the sidewall.

8. The electronic device of claim 5, wherein the panel body further comprises a plurality of posts, the sheet further defines a plurality of receiving holes for receiving the plurality of posts, the plurality of posts extend through the plurality of receiving holes and the top ends of the plurality of posts are riveted to fix the push button to the sheet.
